(19) United States
(12) Patent Application Publication
(10) Pub. No.: US 2009/0137107 A1
(43) Pub. Date: May 28, 2009

(54) METHOD OF MANUFACTURING SEMICONDUCTOR DEVICE

(76) Inventor: Takaharu Itani, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/323,977

(22) Filed: Nov. 26, 2008

(30) Foreign Application Priority Data
Nov. 27, 2007 (JP) 2007-305512

(51) Int. Cl. H01L 21/283

(52) U.S. Cl. 438/586; 257/E21.159

(57) ABSTRACT

A method of manufacturing a semiconductor device according to an embodiment of the invention includes forming patterns on a substrate, depositing a light absorption layer on the patterns, processing the light absorption layer to form a first region which includes a first type of pattern included in the patterns and is coated with the light absorption layer having a first thickness, a second region which includes a second type of pattern included in the patterns and is coated with the light absorption layer having a second thickness thinner than the first thickness, and a third region which includes a third type of pattern included in the patterns and is coated with the light absorption layer having a third thickness thinner than the second thickness, and annealing the substrate by radiating light on the substrate.

### CROSS REFERENCE TO RELATED APPLICATION

This application is based upon and claims the benefit of priority from the prior Japanese Patent Application No. 2007-305512, filed on Nov. 27, 2007, the entire contents of which are incorporated herein by reference.

### BACKGROUND OF THE INVENTION

1. Field of the Invention

The present invention relates to a method of manufacturing a semiconductor device.

2. Background Art

Generally, miniaturization of an LSI improves the performance of the LSI. This is because reductions of the dimensions of a transistor and a line can improve switching speed of the transistor and processing speed of the LSI. Therefore, to improve the performance of the LSI, miniaturization of the LSI has been promoted. However, to miniaturize the LSI, not only the dimensions of the transistor and line, but also the dimension of a diffusion layer must be reduced. Particularly, the dimension of the diffusion layer must be reduced not only in the horizontal direction but also in the vertical direction. Therefore, it is demanded to form a shallow diffusion layer having a low resistance.

Generally, a process for forming a diffusion layer includes an ion implanting process for implanting impurity ions in a semiconductor substrate, and an activation annealing process for activating implanted impurity atoms. When a silicon substrate is adopted as the semiconductor substrate, atoms of group III element such as boron, or atoms of group V element such as arsenic or phosphorus, are implanted as impurity atoms. To form a shallow diffusion layer, impurities must be implanted shallowly. For this reason, acceleration energy, which is an important factor for determining an implantation depth in the ion implanting process, has been lowered year by year. In recent years, impurities are implanted using marginal acceleration energy.

On the other hand, in the activation annealing process, heat treatment must be performed at a high temperature of 1000° C. or higher to improve the activation rate of impurities. However, the diffusion coefficient of impurities increases with temperature, and this causes an increase of the diffusion length of the impurities. This makes it difficult to form a shallow junction.

Regarding the activation annealing process, a lamp annealing apparatus and a laser annealing apparatus attract attentions.

However, since lamp annealing requires a heating time of at least several seconds, the annealing temperature is equalized by heat diffusion. Therefore, in lamp annealing, it is difficult to vary the annealing temperature between predetermined regions.

On the other hand, in laser annealing, since heating time is in the order of milliseconds and the effect of equalization is small, temperature difference is easily created on the substrate. However, in laser annealing, respective regions on a chip cannot be equally heated if a part of patterns has been already formed on the chip. Thereby, characteristics of the transistor are fluctuated, and the yield and productivity of the LSI are negatively affected.

JP-A H8-139016 (KOKAI) discloses a method of manufacturing a thin film integrated circuit, the method including a step of forming a light absorption layer on an insulating substrate. Further, JP-A H9-260286 (KOKAI) discloses a method of manufacturing a semiconductor device, the method including a step of selectively forming an anti-reflection layer in a predetermined region on a substrate. However, it is not allowed to achieve the objects with the layers formed by these methods, in some cases.

### SUMMARY OF THE INVENTION

An aspect of the present invention is, for example, a method of manufacturing a semiconductor device, the method including forming patterns on a substrate, depositing a light absorption layer on the patterns, processing the light absorption layer to form a first region which includes a first type of pattern included in the patterns and is coated with the light absorption layer having a first thickness, a second region which includes a second type of pattern included in the patterns and is coated with the light absorption layer having a second thickness thinner than the first thickness, and a third region which includes a third type of pattern included in the patterns and is coated with the light absorption layer having a third thickness thinner than the second thickness, and annealing the substrate by radiating light on the substrate.

Another aspect of the present invention is, for example, a method of manufacturing a semiconductor device, the method including forming patterns on a substrate, depositing a light absorption layer on the patterns, processing the light absorption layer to form a first region which includes a first type of pattern included in the patterns and is coated with the light absorption layer having a first thickness, a second region which includes a second type of pattern included in the patterns and is coated with the light absorption layer having a second thickness thinner than the first thickness, and a third region which includes a third type of pattern included in the patterns and from which the light absorption layer is removed, and annealing the substrate by radiating light on the substrate.

### BRIEF DESCRIPTION OF THE DRAWINGS

FIG. 1 is a drawing for showing a manufacturing process of a semiconductor device according to a first embodiment;

FIG. 2 is a drawing for showing the manufacturing process according to the first embodiment;

FIG. 3 is a drawing for showing variations of the manufacturing process according to the first embodiment;

FIG. 4 is a drawing for illustrating the arrangement of gate conductors;

FIG. 5 is a drawing for illustrating the thickness of a light absorption layer;

FIG. 6 is a graph showing results of evaluation for the performance of transistors;

FIG. 7 is a drawing for showing a manufacturing process of a semiconductor device according to a second embodiment;

FIG. 8 is a drawing for illustrating the thickness of a light absorption layer; and

FIG. 9 is a graph showing results of evaluation for the performance of transistors.

### DESCRIPTION OF THE EMBODIMENTS

First, problems of the activation annealing process in the diffusion layer forming process will be described in detail on the basis of findings of the inventors.

In the activation annealing process, a lamp annealing apparatus is often used. The lamp annealing apparatus is generally equipped with a processing chamber for placing a substrate to be processed, a gas pipe for introducing into the processing chamber a gas that makes the processing chamber in an inert atmosphere, and a halogen lamp disposed outside the processing chamber so as to face the substrate via a transparent material, such as quartz. In heat treatment, the lamp is lit, and the substrate is heated by radiant light emitted from the lamp.

In activation annealing by the lamp annealing apparatus, temperature of the substrate is controlled so as to be increased at a speed of, for example, about 50° C./sec, maintained at a temperature between 1,000° C. and 1,100° C. for about 10 seconds to 30 seconds, and then lowered at a speed of about 20° C./sec. In recent years, however, for necessity of suppressing the diffusion of impurities to form shallow junction, temperature conditions for further suppressing the diffusion of impurities during temperature increasing, maintaining, and lowering have been adopted. In this case, temperature of the substrate is controlled so as to be rapidly increased at a speed of, for example, about 150° C./sec, and when the temperature reaches between 1,000° C. and 1,100° C., the temperature is immediately lowered rapidly at a speed of about 60° C./sec. In this case, time for maintaining the temperature at 1,000° C. to 1,100° C. is controlled, for example, to 1 second or shorter. Such annealing is referred to as “spike annealing.” By combining ion implantation using a low accelerating energy with activation annealing using spike annealing, a diffusion layer of a junction depth of about 20 nm to 30 nm having a relatively low resistance can be formed. A depth when the concentration of impurities in the substrate becomes 1×18 cm⁻³ is referred to as the “junction depth.”

Due to further development of miniaturization of an LSI, it is demanded to form a diffusion layer of a shallower junction depth of 10 nm to 20 nm having a lower resistance. However, since diffusion of impurities during temperature increasing and lowering is unavoidable by activation annealing using a lamp annealing apparatus, it is difficult to form such a diffusion layer using the lamp annealing apparatus. In recent years, therefore, as an annealing apparatus that can shorten the heating time of the substrate including the time for temperature increasing and lowering to the order of milliseconds, a flash lamp annealing apparatus and a laser annealing apparatus attract attentions.

The laser annealing apparatus is generally equipped with a laser oscillating source used as a light source, an optical system including a mirror for guiding light to the substrate to be processed and the like, a movable stage for placing the substrate, and a processing chamber provided with a stage. The laser annealing apparatus can scan the substrate with laser beams by moving the stage at a high speed. Time to irradiate a certain point on the substrate with laser beams is as short as 10 milliseconds or shorter. Furthermore, the laser annealing apparatus can heat the substrate to a temperature of 1,000° C. or higher by appropriately controlling the output of the laser oscillating source. Since the laser annealing apparatus can reduce the total of the temperature increasing time and the temperature lowering time to 10 milliseconds or shorter, it can also form a shallow diffusion layer with a lowered resistance while suppressing the diffusion of impurities. Therefore, it is studied to apply the laser annealing apparatus to the LSI manufacturing process.

However, the heat treatment using the laser annealing or flash lamp annealing apparatus has following problems.

The first problem is an occurrence of temperature difference on the substrate depending on a pattern formed on the substrate. When activation annealing is implemented, a part of patterns is previously formed on the substrate. For example, an STI (shallow trench isolation), an AA (active area), and a GC (gate conductor) forming gate electrodes are previously formed on the substrate, in many cases. When the substrate is a silicon substrate, the STI and GC are generally formed of silicon oxide and polysilicon, respectively.

Normally, the STI, AA, and GC are not always evenly present in each region in a chip. For example, the existing density of STI, AA, and GC are generally different among the memory circuit, the logic circuit, and peripheral I/O circuits. Therefore, when light is radiated on the substrate, a phenomenon wherein the absorptance of light differes each region on the substrate occurs. Therefore, in laser annealing, the annealing temperature differs each region on the substrate occurs. This means that respective regions in a chip cannot be evenly heated. Thereby, characteristics of the transistor are fluctuated, and the yield and productivity of the LSI are negatively affected.

As an approach for preventing such a problem, an approach for forming a light absorption layer on the substrate has been proposed. In such an approach, by forming a layer having a high radiation factor, only a predetermined ratio of radiant light is made to be absorbed in such a layer, and the substrate is heated by thermal conduction. Thereby, the effect of the pattern density can be suppressed.

However, the presence of a problem that cannot be solved only by forming a light absorption layer was clarified by the inventors' studies. Since heating by laser beams is rapidly performed, thermal equilibrium is often not realized. Therefore, temperature difference occurs between regions where materials having different thermal conductivity are present. For example, although polysilicon, which is the material for GC, and single crystal silicon, which is the material for the substrate, have an equivalent thermal conductivity of about 1.3 W/cm·K, the thermal conductivity of silicon oxide, which is the material for STI is about 0.0015 W/cm·K, which is much smaller than the thermal conductivity of silicon. Therefore, the quantity of heat diffused into the substrate from the GC on the STI is smaller than the quantity of heat diffused into the substrate from the GC on the substrate, and the time when the GC on the STI is maintained at a high temperature becomes longer than the time when the GC on the substrate is maintained at a high temperature. Therefore, the situation wherein the GC on the STI is heated to a temperature exceeding the melting point, and is melted, can occur. On the other hand, if the irradiation energy of laser beams is lowered so as not to melt the GC on the STI, the primary object to sufficiently activate impurities cannot be achieved.

An approach for changing light absorptance of each region by patterning the light absorption layer to form portions having and not having the light absorption layer has also proposed. However, only two levels in light absorptance can be established by this approach. Since various kinds of layers are present on the substrate, it is difficult to suppress the fluctuation of annealing temperatures only by the presence or absence of the light absorption layer.

The second problem is that when temperature difference is intentionally required on the substrate on the contrary to the above case, there is no method to realize such a situation. This causes a problem, for example, in forming a metal silicide. The metal silicide is often formed on the surface of a gate electrode or a source/drain region. The metal silicide is formed by forming a metal layer on the surface of a gate electrode or a source/drain region, and heat-treating the substrate to allow silicon atoms in the gate electrode or the source/drain region to react with metal atoms in the metal layer. Unreacted metal is removed using a chemical solution after heat treatment.

In this process, when the area of STI around the gate electrode or the source/drain region is extremely larger than the area of the gate electrode or the source/drain region, a large quantity of metal atoms are present around the gate electrode or the source/drain region. In this case, metal atoms are excessively supplied to the gate electrode or the source/drain region. Therefore, an abnormal reaction occurs and a normal metal silicide cannot be formed. This causes a problem wherein the contact resistance in the gate electrode or the source/drain region does not meet standards.

Although this problem is considered to be solved by changing annealing temperatures of each region in forming the metal silicide, there is no method to realize such a situation. For example, in lamp annealing, since at least several seconds of heating is required, the annealing temperature is equalized by thermal diffusion. Therefore, it is difficult to change annealing temperatures of each predetermined region.

On the other hand, in laser annealing, since the heating time is in the order of milliseconds and the effect of equalization is small, temperature difference can be easily created on the substrate. However, in laser annealing, respective regions on a chip cannot be evenly heated if a part of patterns has been already formed on the chip. Thereby, characteristics of the transistor are fluctuated, and the yield or productivity of the LSI is adversely affected. Furthermore, in the above-described approach for forming portions having and not having the light absorption layer to create temperature difference, only two levels in light absorptance can be established. Also, since the reflectance of light is extremely high in the portion where a metal layer is present on the surface, little light is absorbed in the portion where the metal layer is present but no light absorption layer is present, and it is difficult to heat such a portion. Therefore, it is difficult to apply this approach to laser annealing in forming the metal silicide.

Embodiments of the present invention will be described with reference to the drawings. In the drawings, identical or similar parts are denoted by identical or similar reference numerals. The drawings are schematic, and the ratios of various dimensions in the drawings do not necessarily agree with actual ratios.

### First Embodiment

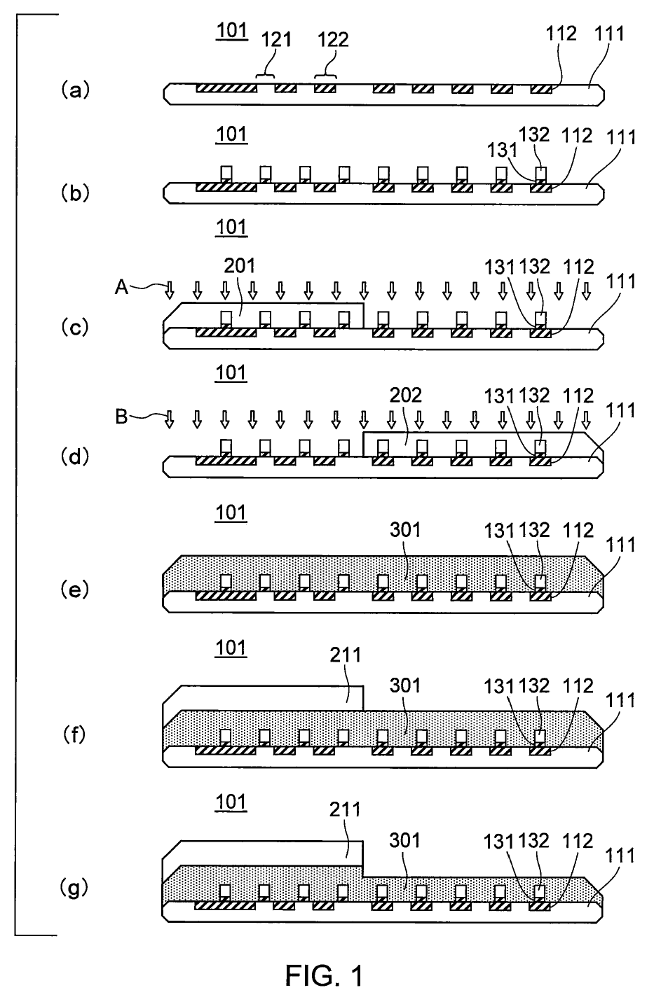

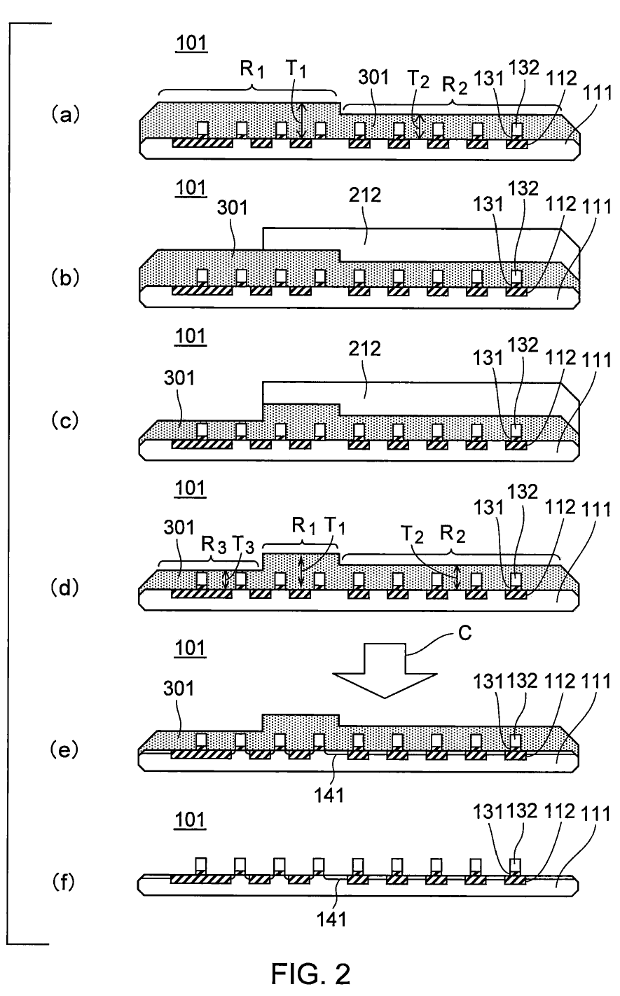

FIGS. 1 and 2 show a manufacturing process of a semiconductor device 101 according to a first embodiment.

First, as shown in FIG. 1a, an isolation layer 112 is formed on a substrate 111 using a known method. Here, the substrate 111 is a silicon substrate (silicon wafer). The substrate 111 may be a semiconductor substrate or an SOI (semiconductor on insulator) substrate. The isolation layer 112 in this embodiment is an STI (shallow trench isolation) layer. Here, the isolation layer 112 is a silicon oxide layer. FIG. 1a shows substrate regions 121 and isolation regions 122. On the substrate regions 121, the surface of the substrate 111 is not coated with the isolation layer 112. On the isolation regions 122, the surface of the substrate 111 is coated with the isolation layer 112.

The isolation layer 112 is formed, for example, as follows. First, a thermal silicon oxide layer is deposited on the substrate 111, and a silicon nitride layer is formed on the thermal silicon oxide layer. Next, a photoresist is applied on the silicon nitride layer, and the photoresist is patterned. Then, the silicon nitride layer and the thermal silicon oxide layer are partially removed by dry etching using the photoresist as a mask to partially expose the substrate 111. Next, the photoresist is removed using a chemical solution or by ashing. Then, a trench for isolation is formed on the surface of the substrate 111 by dry etching using the silicon nitride layer and the thermal silicon oxide layer as a mask. Next, a plasma oxide layer is buried in the trench, the plasma oxide layer is planarized by CMP or the like, and the silicon nitride layer and the thermal silicon oxide layer are removed. Thereby, the isolation layer 112 is formed. Next, ion implantation for forming well regions and channel regions is performed. In the ion implantation, ions of impurities, such as boron, arsenic, or phosphorus, are implanted into each region. Thereafter, activation annealing for activating the implanted impurities is performed.

Next, as shown in FIG. 1b, a gate insulation film 131 is formed on the substrate 111. Here, the gate insulation film 131 is a silicon oxide layer. Then, a conductive layer that forms a gate electrode 132 is formed on the gate insulation film 131. The conductive layer is a gate conductor (GC). Here, the conductive layer is a polysilicon layer. Hence, the gate electrode 132 in this embodiment is a polysilicon electrode. In this way, patterns formed of the conductive layer are formed on the substrate 111.

The gate insulation film 131 and the gate electrode 132 are formed, for example, as follows. First, the gate insulation film 131 is deposited on the substrate 111. Next, a polysilicon layer is deposited on the gate insulation film 131 by LPCVD. Then, the polysilicon layer and the gate insulation film 131 are patterned by photolithography and dry etching. The polysilicon layer patterned in this process becomes the gate electrode (gate conductor) 132. Thereafter, sidewall insulation films are formed on the sides of the gate electrode 132. The sidewall insulation films include silicon oxide layers or/and silicon nitride layers.

Next, as shown in FIG. 1c, a pattern of a photoresist 201 is formed. Then, as shown by arrows A, ions of group III element are implanted into the region for forming a p-MOS. The ion species are boron ions or boron difluoride ions, for example. Thereby, impurities are introduced into the gate electrode (gate conductor) 132 and source/drain regions in the p-MOS region.

Next, as shown in FIG. 1d, a pattern of a photoresist 202 is formed. Then, as shown by arrows B, ions of group V element are implanted into the region for forming an n-MOS. The ion species are phosphorus ions or arsenic ions, for example. Thereby, impurities are introduced into the gate electrode (gate conductor) 132 and source/drain regions in the n-MOS region.

Next, heat treatment for activation (activation annealing) is performed. By performing the heat treatment at a high temperature, the electrical activation rate of impurity atoms implanted into the gate electrode 132 and the source/drain regions can be increased. Thereby, depletion of the gate electrode 132 can be suppressed, and the resistances of the source/drain regions can be lowered. This improves characteristics of a transistor. On the other hand, unless diffusion of the impurity atoms is suppressed, the impurity atoms also diffuse to the channel regions. This deteriorates characteristics of the transistor. Therefore, laser annealing, which can increase the temperature of the substrate 111 to 1,000° C. or higher in several milliseconds, is applied as the activation annealing.

In this embodiment, before performing activation annealing by laser annealing, a light absorption layer is deposited on the entire surface of the substrate 111. Further in this embodiment, before the activation annealing, the thickness of the light absorption layer is changed depending on the position by photolithography and etching. The light absorption layer is formed, for example, as follows.

First, as shown in FIG. 1e, a light absorption layer 301 is deposited on the substrate 111 and the gate electrode (gate conductor) 132. Thereby, the light absorption layer 301 having a constant thickness is formed on the entire surface of the substrate 111. The light absorption layer 301 is, for example, a silicon oxide layer, a silicon nitride layer, or a laminated layer including these layers. The light absorption layer 301 may be, for example, a layer mainly formed of carbon. This is an example of a layer containing carbon. As the light absorption layer 301, layers other than those described above may be used as long as the absorptance for the wavelength of a laser beam to be used is not zero.

Next, as shown in FIG. 1f, a pattern of a photoresist 211 is formed on the light absorption layer 301 by photolithography. Then, as shown in FIG. 1g, the light absorption layer 301 is processed by dry etching using the photoresist 211 as a mask. Thereby, the light absorption layer 301 is partially thinned. Next, as shown in FIG. 2a, the photoresist 211 is removed by a chemical solution or ashing. Thereby, the light absorption layer 301 whose thickness is changed in two levels within a range of a chip is formed. On the substrate 111, a first region R₁ coated with the light absorption layer 301 having a first thickness T₁, and a second region R₂ coated with the light absorption layer 301 having a second thickness T₂ thinner than the first thickness T₁ are formed.

Next, as shown in FIG. 2b, a pattern of a photoresist 212 is formed on the light absorption layer 301 by photolithography. Then, as shown in FIG. 2c, the light absorption layer 301 is processed by dry etching using the photoresist 212 as a mask. Thereby, the light absorption layer 301 is partially thinned. Next, as shown in FIG. 2d, the photoresist 212 is removed by a chemical solution or ashing. Thereby, the light absorption layer 301 whose thickness is changed in three levels within a range of a chip is formed. On the substrate 111, the first region R₁ coated with the light absorption layer 301 having the first thickness T₁, the second region R₂ coated with the light absorption layer 301 having the second thickness T₂ thinner than the first thickness T₁, and a third region R₃ coated with the light absorption layer 301 having a third thickness T₃ thinner than the second thickness T₂ are formed.

As described above, the substrate 111 is provided with the patterns formed of the conductive layer 132. The patterns are classified into three types of pattern according to the relation between the isolation layer 112 and the conductive layer 132. The first region R₁ includes a first type of pattern included in the patterns. The second region R₂ includes a second type of pattern included in the patterns. The third region R₃ includes a third type of pattern included in the patterns. Details of the first to third types of pattern are described below.

In this embodiment, the third region R₃ is formed after forming the second region R₂. However, the third region R₃ may be formed before forming the second region R₂.

Next, as shown in FIG. 2e, the substrate 111 having the first to third regions R₁ to R₃ is annealed by activation annealing. In other words, the substrate 111 is annealed by radiating a laser beam onto the substrate 111. FIG. 2e shows, by an arrow C, the laser beam irradiated onto the substrate 111. Here, activation annealing is performed under scanning conditions of an irradiation energy density of the laser beam of 40 J/cm², and a heating time of 1 millsecond. By the activation annealing, impurities in the gate electrode (gate conductor) 132 and the source/drain regions 141 are activated, and the gate electrode (gate conductor) 132 and the source/drain regions 141 are completed. Next, as shown in FIG. 2f, the light absorption layer 301 is removed by a chemical solution or ashing.

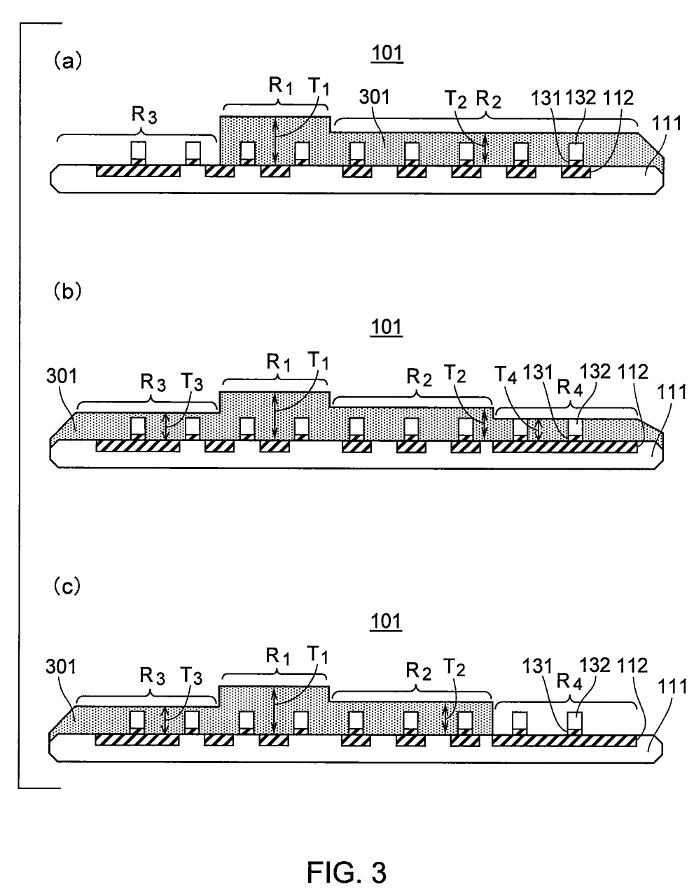

In the step shown in FIG. 2c, the light absorption layer 301 may be removed instead of being thinned. Thereby, a substrate 111 as shown in FIG. 3a can be obtained instead of the substrate 111 as shown in FIG. 2d. In FIG. 3a, a first region R₁ coated with the light absorption layer 301 having a first thickness T₁, a second region R₂ coated with the light absorption layer 301 having a second thickness T₂ thinner than the first thickness T₁ and a third region R₃ from which the light absorption layer 301 is removed are formed. In this embodiment, a light absorption layer 301 whose thickness is changed in four or more levels may be formed instead of the light absorption layer 301 whose thickness is changed in three levels. Each of FIGS. 3b and 3c shows an example of a substrate 111 having such light absorption layer 301. In a fourth region R₄ shown in FIG. 3b, the light absorption layer 301 is thinned. In a fourth region R₄ shown in FIG. 3c, the light absorption layer 301 is removed.

The light absorption layer 301 in this embodiment will be described in detail with reference to FIG. 2d. However, the following description can be applied not only to the light absorption layer 301 whose thickness is changed in three levels, but also to the light absorption layer 301 whose thickness is changed in four or more levels.

The extinction coefficient is one of indices that indicate optical characteristics of the light absorption layer 301. When the extinction coefficient of the light absorption layer 301 is constant, the light absorptance of the light absorption layer 301 varies according to the thickness of the light absorption layer 301. When the extinction coefficient of the light absorption layer 301 is represented by “K”, and the light absorptance of the light absorption layer 301 having thicknesses of T₁, T₂, and T₃ are represented by A₁, A₂, and A₃, the following relationship is considered to be approximately true:

A₁:A₂:A₃=KT₁:KT₂:KT₃ (1).

Therefore, the following relationship is considered to be approximately true between the thickness T_{N} and the light absorptance A_{N}.

A_{N}=CKT_{N} (2)

where “N” is 1, 2, or 3, and “C” is a constant.

Here, light incident into the light absorption layer 301, not absorbed in the light absorption layer 301, but reaching the surface of the substrate 111, is considered. The quantity of the light is represented by “Q”, and the reflectance on the surface of the substrate 111 is represented by “R”. In this case, the quantity of the light absorbed in the substrate 111 is (131 R)Q, and the quantity of the light not absorbed in the substrate 111 but reflected is RQ. A part of the reflected light RQ is absorbed in the light absorption layer 301.

Here, the energy density of the light incident onto a unit area of the light absorption layer 301 is represented by “W”. Further, the energy density of light incident and absorbed into the light absorption layer 301 is represented by W₁. Further, the energy density of light not absorbed into the light absorption layer 301 but reaching the substrate 111 is represented by W₂. Further, the energy density of light absorbed into the substrate 111 is represented by W₃. Further, the energy density of light not absorbed into the substrate 111 but reflected on the substrate 111 is represented by W₄. Further, the energy density of light reflected on the substrate 111 and absorbed into the light absorption layer 301 is represented by W₅. In this case, W₁, W₂, W₃, W₄, and W₅ are given as follows:

W₁=WA_{N}=WCKT_{N} (3),

W₂=W(1−A_{N})=W(1−CKT_{N}) (4),

W₃=W₂(1−R)=W(1−R)(1−A_{N}) (5),

W₄=W₂R=WR(1−A_{N}) (6),

W₅=W₄A_{N}=WR(1−A_{N})A_{N} (7).

The quantity of light absorbed in the substrate 111 and the light absorption layer 301 is represented by W_{T}. The quantity of the light W_{T} is given as follows:

$$\begin{matrix}{W}_{T} = {W}_{1} + {W}_{3} + {W}_{5} \\ = W \{ {A}_{N} + ( 1 - R ) ( 1 - {A}_{N} ) + R ( 1 - {A}_{N} ) {A}_{N} \} \\ = W \{ 1 - {R ( 1 - {A}_{N} )}^{2} \} .\end{matrix} \qquad ( 8 )$$

Therefore, W{1−R(1−A_{N})²} is the effective quantity of absorbed light. Consequently, the light absorptance W_{T}/W, which is the ratio of the quantity of absorbed light to the quantity of incident light, is {1−R(1−A_{N})²} where 0<A_{N}<1. Since W_{T} is a function of A_{N}, and A_{N} is a function of T_{N}, W_{T} becomes a function of T_{N}. In other words, the quantity of light absorbed in the substrate 111 and the light absorption layer 301 is varied according to the thickness of the light absorption layer 301. Therefore, the annealing temperature for the substrate 111 is varied according to the thickness of the light absorption layer 301.

In this embodiment, the thickness of the light absorption layer 301 is changed depending on the arrangement of the gate conductor (GC) 132.

Generally, the gate conductor 132 is formed ranging from the substrate region 121 to the isolation region 122. Details of the substrate region 121 and the isolation region 122 are shown in FIG. 1a. In this embodiment, the first region R₁ is formed in a region where the gate conductor 132 is formed on the substrate region 121. On the other hand, the second region R₂ and the third region R₃ are formed in a region where the gate conductor 132 is formed on the isolation region 122. Generally, the gate conductor 132 has a portion present on the substrate region 121 and a portion present on the isolation region 122, and the area of the former portion is generally smaller than the area of the latter.

The substrate 111 is usually provided with isolation layers 112 having various areas. For example, the areas of the isolation layers 112 in a memory circuit are usually smaller than the areas of the isolation layers 112 in a peripheral I/O circuit. In this embodiment, the second region R₂ is formed in a region where the gate conductor 132 is formed on a relatively small isolation layer 112, and the third region R₃ is formed in a region where the gate conductor 132 is formed on a relatively large isolation layer 112. For example, the second region R₂ is formed in a region where the gate conductor 132 is formed on an isolation layer 112 whose area is smaller than a threshold. Further, the third region R₃ is formed in a region where the gate conductor 132 is formed on an isolation layer 112 whose area is larger than the threshold. In a region where the gate conductor 132 is formed on the isolation layer 112 whose area is equal to the threshold, either the second region R₂ or the third region R₃ may be formed.

Polysilicon, which is the material for the gate conductor 132, has a thermal conductivity of about 1.3 W/cm·K. This is substantially equal to the thermal conductivity of single crystal silicon, which is the material for the substrate 111. On the other hand, silicon dioxide, which is the material for the isolation layers 112, has a thermal conductivity of about 0.0015 W/cm·K. This is much lower than the thermal conductivity of silicon. Therefore, in the laser annealing of the substrate 111, heat is difficult to be transferred to the substrate 111 in a region having dense isolation layers 112, while heat is easily transferred to the substrate 111 in a region having coarse isolation layers 112. A high thermal conductivity means that the distance where heat is diffused in a certain period of time is long. The temperature of the portion heated by the laser is lowered by the diffusion of heat to the periphery. Therefore, the temperature of the material having a higher thermal conductivity tends to be lowered more rapidly than the material having a lower thermal conductivity. In other words, the substrate region 121 tends to be relatively easily cooled, and the isolation region 122 tends to be relatively difficult to be cooled.

Therefore, in the laser annealing of the substrate 111, the gate conductor 132 on the substrate region 121, the gate conductor 132 on the relatively small isolation layer 112, and the gate conductor 132 on the relatively large isolation layer 112 have different temperature histories. As a result, annealing temperature of the gate conductor 132 becomes different depending on the position. In this embodiment, therefore, the thickness of the light absorption layer 301 is changed depending on the arrangement of the gate conductor 132 to suppress difference in annealing temperature between gate conductors 132.

As described above, the substrate 111 is provided with the patterns formed of the conductive layer (gate conductor) 132. The patterns are classified into three types of pattern according to the relation between the isolation layer 112 and the conductive layer 132. The first, second, and third regions R₁, R₂, and R₃ include the first, second, and third types of pattern included in the patterns, respectively. Hereinafter, the patterns are referred to as conductor patterns.

In this embodiment, the first region R₁ includes, as the first type of pattern, a conductor pattern formed on the substrate region 121. Further, the second region R₂ includes, as the second type of pattern, a conductor pattern formed on an isolation layer 112 having an area smaller than the above-mentioned threshold. Further, the third region R₃ includes, as the third type of pattern, a conductor pattern formed on an isolation layer 112 having an area larger than this threshold.

In this way, region segmentation such that each of the first to third regions R₁ to R₃ includes a pattern is assumed in this embodiment. In this embodiment, the first, second, and third regions R₁, R₂, and R₃ include the first, second, and third types of pattern, respectively. This can suppress difference in annealing temperature between different patterns. On the other hand, region segmentation such that the first to third regions R₁ to R₃ are included in patterns is not assumed in this embodiment. This is because such segmentation cannot suppress difference in annealing temperature between different patterns. For example, this embodiment does not include region segmentation such that the first and second regions R₁ and R₂ are included in the same pattern, and become one portion and the other portion in this pattern respectively.

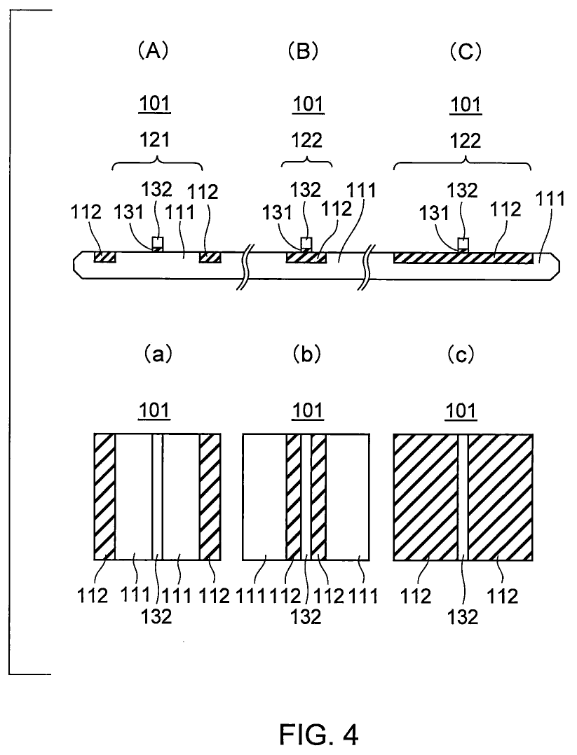

FIG. 4 is a drawing for illustrating the arrangement of the gate conductor 132. FIGS. 4A and 4a show the gate conductor 132 formed on the substrate region 121. FIGS. 4A and 4a show a sectional view and a plan view, respectively. FIGS. 4B and 4b show the gate conductor 132 formed on the relatively small isolation layers 112. FIGS. 4B and 4b show a sectional view and a plan view, respectively. FIGS. 4C and 4c show the gate conductor 132 formed on the relatively large isolation layer 112. FIGS. 4C and 4c show a sectional view and a plan view, respectively.

Examples of the laser for laser annealing include a semiconductor laser having a wavelength of 0.78 to 0.98 μm, and an Nd:YAG laser having a wavelength of 1.0 to 1.1 μm. However, the laser for laser annealing is not limited to such lasers. In this embodiment, the light absorption layer 301 is formed by depositing a layer mainly formed of carbon. The extinction coefficient “K” of this light absorption layer 301 to the lasers in the examples is 0.15.

Here, an example of a method of processing the light absorption layer 301 will be described. In the region shown in FIG. 4A, since it is desired to highly activate impurities in the substrate 111 and the gate conductor 132, the light absorption layer 301 is thickened. The thickness of the light absorption layer 301 in the region in FIG. 4A is, for example, 4 μm. In the region shown in FIG. 4C, the light absorption layer 301 is thinned for preventing dissolution of the gate conductor 132. The thickness of the light absorption layer 301 in the region in FIG. 4C is, for example, 2 μm. The thickness of the light absorption layer 301 in the region shown in FIG. 4B is set between the thickness in the region in FIG. 4A and the thickness in the region in FIG. 4C. The thickness of the light absorption layer 301 in the region in FIG. 4C is, for example, 3 μm. In this way, the substrate 111 is provided with the first region R₁ coated with the light absorption layer 301 having the first thickness T₁ (=4 μm), the second region R₂ coated with the light absorption layer 301 having the second thickness T₂ (=3 μm) thinner than the first thickness T₁, and the third region R₃ coated with the light absorption layer 301 having the third thickness T₃ (=2 μm) thinner than the second thickness T₂.

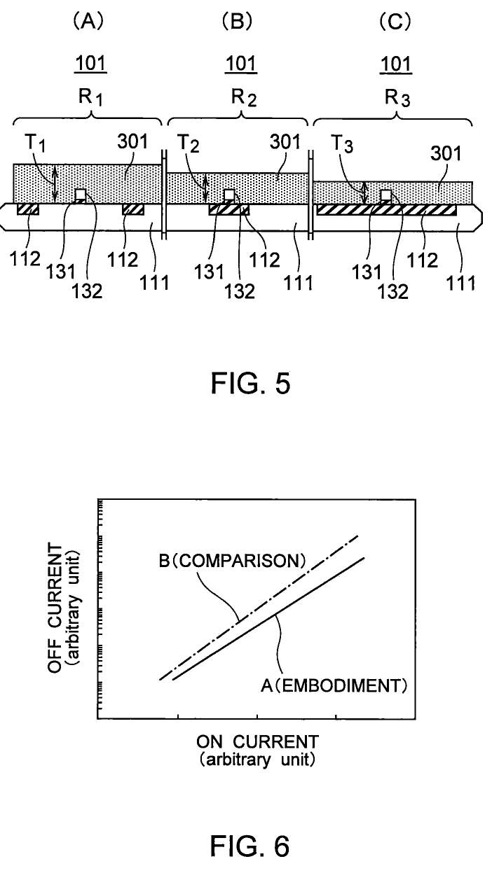

An example of such light absorption layer 301 is shown in FIG. 5. FIG. 5 is a drawing for illustrating the thickness of the light absorption layer 301. FIG. 5A shows the gate conductor 132 formed on the substrate region 121, similar to FIG. 4A. The region shown in FIG. 5A is the first region R₁. FIG. 5B shows the gate conductor 132 formed on the relatively small isolation layer 112, similar to FIG. 4B. The region shown in FIG. 5B is the second region R₂. FIG. 5C shows the gate conductor 132 formed on the relatively large isolation layer 112, similar to FIG. 4C. The region shown in FIG. 5C is the third region R₃.

An effective light absorptance W_{T}/W will be calculated. Here, the light absorptance A_{N} of the light absorption layer 301 having a thickness of 2 μm is assumed to be 0.3, and the reflectance R of the substrate 111 is assumed to be 0.3. In this case, the ratio of the effective light absorptance W_{T}/W among the first region R₁ (T₁=4 μm), the second region R₂ (T₂=3 μm), and the third region R₃ (T₃=2 μm) is 0.95, 0.91, and 0.85. In this way, the effective light absorptance W_{T}/W on the substrate 111 is varied about 10%. Thereby, the sufficient activation of impurities in the first region R₁ can be compatible with the prevention of the gate conductor 132 in the third region R₃ from melting.

This embodiment has following advantages.

Firstly, since excessive heating of the gate conductor 132 on the isolation layer 112 can be suppressed by changing the thickness of the light absorption layer 301, this embodiment has an advantage that the degree of freedom in the energy density of the laser beam is high. In a case that the thickness of the light absorption layer 301 is uniform, if the energy density of the laser beam is increased for sufficiently activating the substrate region 121, the gate conductor 132 on the isolation layer 112 may be excessively heated and melted. However, if the energy density of the laser beam is lowered so as not to melt the gate conductor 132 on the isolation layer 112, the activation of the substrate region 121 becomes insufficient. In this embodiment, on the other hand, the substrate region 121 can be sufficiently activated while suppressing excessive heating of the gate conductor 132 on the isolation layer 112.

Secondly, this embodiment has a benefit to moderate change in the light absorptance W_{T}/W. When the portions where the light absorption layer 301 is present and absent are formed, and the thickness of the light absorption layer 301 is changed in two levels, the light absorptance W_{T}/W sharply changes between the former portion and the latter portion. Hence, the sufficient activation of the isolation layer 121 is difficult to be compatible with the prevention of overheating of the gate conductor 132 on the isolation layer 112. In this embodiment, on the other hand, the substrate region 121 is relatively easily activated while suppressing excessive heating of the gate conductor 132 on the isolation layer 112. In this embodiment, the thickness of the light absorption layer 301 may be changed in four or more levels as required.

FIG. 6 is a graph showing results of evaluation for the performance of transistors. The curve “A” indicates a result of evaluation for the performance of a transistor in this embodiment. The transistor is manufactured by the process shown in FIGS. 1 and 2. The curve “B” indicates a result of evaluation for the performance of a transistor in a comparative example. The transistor is manufactured by using a light absorption layer 301 having a uniform thickness. When these transistors were manufactured, laser annealing was performed using the maximum irradiation energy density within a range where the gate conductor 132 was not melted.

Each of the curves “A” and “B” indicates the relationship between an OFF current and an ON current, which flow from a source to a drain, and are measured when the transistor is turned off and turned on respectively. The larger is the ON current compared with a fixed OFF current, the more excellent are characteristics of the transistor. According to FIG. 6, since the ON current in the curve “A” is larger than that in the curve “B”, characteristics of the transistor in this embodiment is shown to be more excellent. According to the manufacturing method in this embodiment, the substrate region 121 can be sufficiently activated without excessively heating the gate conductor 132 on the isolation layer 112. Therefore, according to the manufacturing method in this embodiment, a transistor having excellent characteristics can be manufactured.

As described above, in this embodiment, the thickness of the light absorption layer 301 is changed in three or more levels. Thereby, troubles due to uneven annealing temperature and troubles caused when annealing temperature cannot be changed between regions can be suppressed.

The light absorption layer 301 according to this embodiment is not only useful for activation annealing by the laser beam, but also useful for activation annealing by other light. For example, the light absorption layer 301 according to this embodiment is also useful for activation annealing by a tungsten halogen lamp beam or a xenon flash lamp beam. However, since the control of annealing temperature is required particularly in laser annealing and flash lamp annealing, the light absorption layer 301 according to this embodiment is particularly useful for laser annealing and flash lamp annealing. Furthermore, an example of the light in this embodiment is a laser beam or a flash lamp beam containing at least light having a wavelength of 0.4 to 20 μm. An example of the light is a CO₂ laser having a wavelength of 10.6 μm.

Further, in this embodiment, the first region R₁ may be formed in a p-MOS region (or n-MOS region), the second region R₂ may be formed in an n-MOS region (or p-MOS region), and the third region R₃ may be formed in another region (such as a capacitor region), for example. This is useful, for example, when one of the p-MOS and the n-MOS includes a metal electrode as its gate electrode, and the other of the p-MOS and the n-MOS includes a polysilicon electrode as its gate electrode.

### Second Embodiment

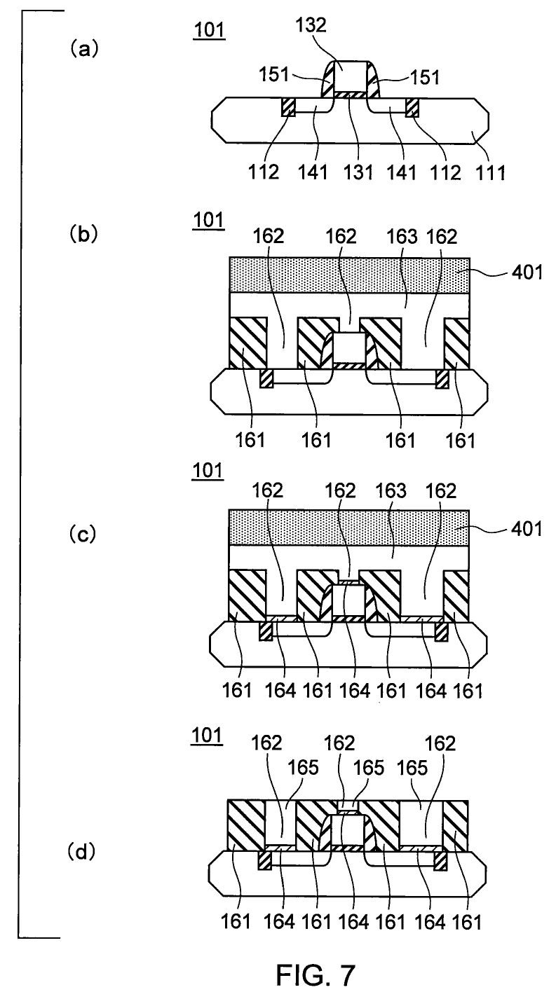

FIG. 7 shows a manufacturing process of a semiconductor device 101 according to a second embodiment. Process charts shown in FIGS. 7a to 7d follow those shown in FIGS. 1a to 1g and FIGS. 2a to 2f.

FIG. 7a shows the substrate 111 immediately after completing the step shown in FIG. 2f. FIG. 7a shows the substrate 111, isolation layer 112, gate insulation film 131, gate electrode 132, source/drain regions 141, and sidewall insulation films 151.

As shown in FIG. 7b, an interlayer insulation film 161 is deposited on the entire surface of the substrate 111 by CVD (chemical vapor deposition) or the like. Thereby, the interlayer insulation film 161 is formed on the substrate 111 and the gate electrode 132. Here, the interlayer insulation film 161 is a silicon oxide layer. Next, the interlayer insulation film 161 is processed by a known method or the like to form contact holes 162 where the surfaces of the substrate 111 and the gate electrode 132 are exposed. Thereby, the surfaces of the substrate 111 (source/drain regions 141) and the gate electrode 132 are exposed. Next, a metal layer 163 is deposited on the entire surface of the substrate 111 by sputtering or the like. Thereby, the metal layer 163 is formed on the surfaces of the substrate 111 and the gate electrode 132. Here, the metal layer 163 is a nickel layer for silicidation.

Next, a light absorption layer 401 is deposited on the metal layer 163. Thereby, the light absorption layer 401 having a constant thickness is formed above the substrate 111. Examples of the light absorption layer 401 are same as those of the light absorption layer 301. Next, the light absorption layer 401 is processed. On the substrate 111, a first region R₁ coated with the light absorption layer 401 having a first thickness T₁, a second region R₂ coated with the light absorption layer 401 having a second thickness T₂ thinner than the first thickness T₁, and a third region R₃ coated with the light absorption layer 401 having a third thickness T₃ thinner than the second thickness T₂ are formed. Examples of a method of processing the light absorption layer 401 are same as those of a method of processing the light absorption layer 301. Next, the substrate 111 having the first to third regions R₁ to R₃ is annealed by silicide annealing. The silicide annealing includes laser annealing. After the laser annealing, an excessive metal layer 163 that has not reacted is removed by a chemical solution. Thereafter, a second annealing is performed using a normally used annealing apparatus. By the silicide annealing, metal silicide layers 164 are formed on the surfaces of the substrate 111 and the gate electrode 132, as shown in FIG. 7c. Details of this step will be described later.

Next, as shown in FIG. 7d, a contact material is buried in the contact holes 162. Thereby, contact plugs 165 are formed on the metal silicide layers 164. Here, the contact plugs 165 are W (tungsten) plugs.

As described above, in this embodiment, laser annealing is used in the process for forming the metal silicide layers 164. The laser annealing will be described below.

In the laser annealing in this embodiment, a laser beam is radiated onto the surface of the metal layer 163. However, since the reflectance of the metal layer 163 is generally high, the metal layer 163 is difficult to be heated by the laser beam. Therefore, in this embodiment, the light absorption layer 401 is formed on the surface of the metal layer 163. Further, in this embodiment, the thickness of the light absorption layer 401 is changed according to the ratio between the area of contact regions (silicide regions) and the area of insulator regions (non silicide regions). Thereby, the annealing temperature is changed according to the ratio between the areas of the contact regions and insulator regions.

Here, the area of the silicide regions, where the metal silicide layers 164 are to be formed, is represented by “S”. In this embodiment, the surfaces of the substrate 111 and the gate electrode 132 exposed in the step shown in FIG. 7b are the silicide regions. In the silicide regions, the metal silicide layers 164 are formed on the surfaces of silicon (here, the silicon substrate and the polysilicon electrode). The area of the non silicide regions, where no metal silicide layer 164 is formed, is represented by “A”. In this embodiment, the non silicide regions are occupied by insulators such as the interlayer insulation film 161.

In laser annealing, whereas metals in the silicide regions react with the silicon, metals in the non silicide regions do not react. Therefore, when the area “A” is sufficiently larger than the area “S”, large quantities of unreacted metal atoms are present around the silicide regions. In this case, excessive metal atoms are supplied to the silicide regions. Therefore, abnormal reactions may occur, and normal metal silicides cannot be formed. Thereby, the contact resistance of the source/drain regions 141 and the gate electrode 132 may be deviated from the standards. Therefore, in this embodiment, in a region where the area “A” is sufficiently larger than the area “S”, the thickness of the light absorption layer 401 is determined so that the annealing temperature is relatively lowered. Thereby, occurrences of abnormal reactions are suppressed.

In this embodiment, when the layout of the semiconductor device 101 is designed, the entire region of a design drawing is divided into square regions of 1 μm×1 μm. Then, the area ratio “α” of the silicide regions within each square region is calculated. The area ratio “α” indicates a ratio of an area of the silicide regions within an area of a square region, and is represented by α=S/(S+A). In this embodiment, the thickness of the light absorption layer 401 in each square region is changed according to the area ratio “α” of the silicide regions within each square region. The square region is an example of a predetermined region of the present invention. The shape of each divided region can be a shape other than square.

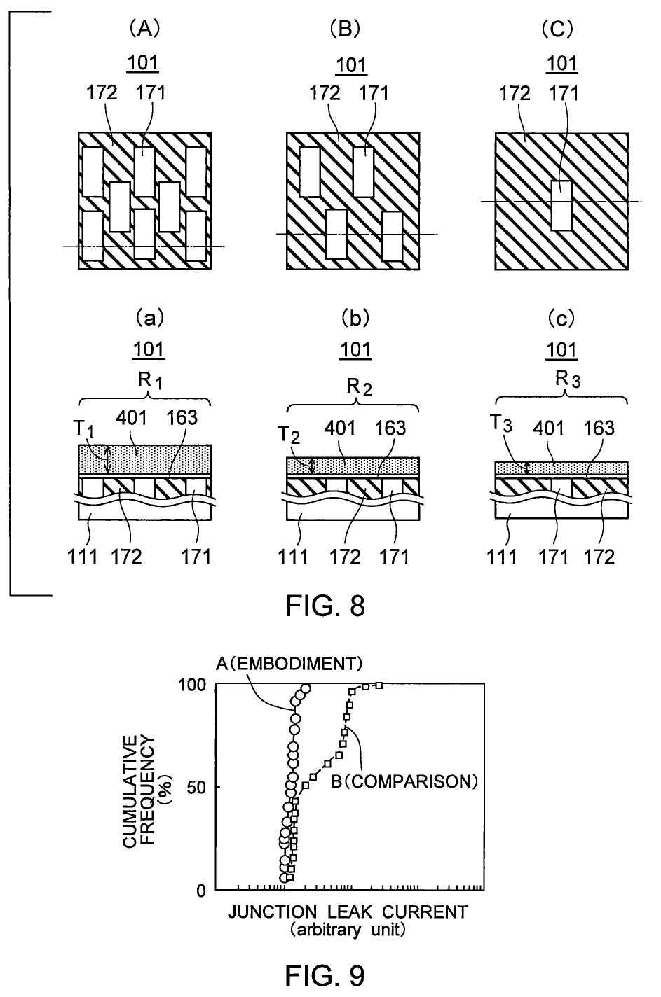

FIG. 8 is a drawing for illustrating the thickness of the light absorption layer 401. Each of FIGS. 8A to 8C is a top view of a square region. Each of FIGS. 8A to 8C schematically shows a silicide region(s) 171 and a non silicide region 172. In this way, patterns formed of the silicide regions 171 are formed on the substrate 111. FIG. 8A shows a square region where the area ratio “a” is larger than a threshold “X”. FIG. 8B shows a square region where the area ratio “α” is smaller than the threshold “X” and larger than a threshold “Y”. FIG. 8C shows a square region where the area ratio “α” is smaller than the threshold “Y”. However, the relation of 0<Y<X<1 is present between the threshold “X” and the threshold “Y”. Here, X=0.5 (50%) and Y=0.1 (10%).

In this embodiment, the first region R₁ is formed in the square region as shown in FIG. 8A, the second region R₂ is formed in the square region as shown in FIG. 8B, and the third region R₃ is formed in the square region as shown in FIG. 8C. They are schematically shown in FIGS. 8a to 8c. FIG. 8a is a sectional view of FIG. 8A, FIG. 8b is a sectional view of FIG. 8B, and FIG. 8c is a sectional view of FIG. 8C. Here, the first thickness T₁ is 1.5 μm, the second thickness T₂ is 0.75 μm, and the third thickness T₃ is 0.5 μm. In a square region where the area ratio “α” is equal to the threshold “X”, the first region R₁ may be formed, or the second region R₂ may be formed. In a square region where the area ratio “α” is equal to the threshold “Y”, the second region R₂ may be formed, or the third region R₃ may be formed.

In this embodiment, the first to third regions R₁ to R₃ are formed by such region segmentation. This segmentation will be described with the concept of first to third types of pattern, similar to the first embodiment.

As described above, the substrate 111 is provided with the patterns formed of the silicide regions 171. The patterns are classified into three types of pattern according to the ratio of the area of the silicide regions 171 within the area of a square region (i.e., the area ratio “a”). The first, second, and third regions R_{1,} R₂, and R₃ include the first, second, and third types of pattern included in the patterns, respectively.

In this embodiment, the first region R₁ includes, as the first type of pattern, the silicide regions 171 formed in a region where the ratio is larger than the first threshold “X”. Further, the second region R₂ includes, as the second type of pattern, the silicide regions 171 formed in a region where the ratio is smaller than the first threshold “X” and larger than the second threshold “Y”. Further, the third region R₃ includes, as the third type of pattern, the silicide regions 171 formed in a region where the ratio is smaller than the second threshold “Y”. In this way, region segmentation such that each of the first to third regions R₁ to R₃ includes a pattern is performed in this embodiment, similar to the first embodiment. This can suppress occurrences of abnormal reactions.

An effective light absorptance W_{T}/W will be calculated. Here, the reflectance of the metal layer 163 is assumed to be 0.7. In this case, the ratio of the effective light absorptance W_{T}/W among the first region R₁ (T₁=1.5 μm), the second region R₂ (T₂=0.75 μm), and the third region R₃ (T₃=0.5 μm) is 0.58, 0.45, and 0.40. In this way, the effective light absorptance W_{T}/W on the substrate 111 is varied more than 10%. Thereby, sufficient change in annealing temperature can be obtained.

In this embodiment, after forming the light absorption layer 401 as shown in FIG. 8, the substrate 111 is subjected to silicide annealing. The silicide annealing will be described below.

First, the substrate 111 is annealed by laser annealing. In other words, the substrate 111 is annealed by radiating a laser beam onto the substrate 111. Here, laser annealing is performed under scanning conditions of laser beam irradiation energy density of 20 J/cm², and a heating time of 1 millisecond. Next, the light absorption layer 401 is removed by a chemical solution or ashing. Next, the substrate 111 is immersed in a chemical solution to remove unreacted nickel atoms. Here, the chemical solution is a mixed solution of sulfuric acid and hydrogen peroxide solution.

Next, the substrate 111 is annealed by lamp annealing. Here, the lamp annealing is performed in an inert gas atmosphere at a temperature between 450° C. and 600° C. for 30 to 60 seconds. Thereby, nickel reacts with silicon completely to form nickel silicide layers. As described above, in this embodiment, laser annealing is performed in the first annealing process, and lamp annealing is performed in the second annealing process. In this embodiment, since excessive nickel is removed after the first annealing, lamp annealing can be adopted as the second annealing. As the first annealing, flash lamp annealing may be adopted.

FIG. 9 is a graph showing results of evaluation for the performance of transistors. The curve “A” indicates results of evaluation for the performance of 20 transistors in this embodiment. The transistors were manufactured by the manufacturing process as shown in FIGS. 7a to 7d. The curve “B” indicates results of evaluation for the performance of 20 transistors in a comparative example. The transistors were manufactured using a light absorption layer 401 having a uniform thickness.

Each of the curves “A” and “B” indicates junction leak characteristics of 20 transistors. In the comparative example, it is shown that there are some transistors whose junction leaks are abnormally large. While in this embodiment, it is shown that there is no transistor whose junction leak is abnormally large. Therefore, according to the manufacturing method of this embodiment, it is expected that transistors exhibiting favorable junction leak characteristics are manufactured.

In the process of manufacturing the semiconductor device 101, both of the light absorption layers 301 and 401 may be used, or any one of the light absorption layers 301 and 401 may be used. Further, the description for the light absorption layer 301 can be also applied to the light absorption layer 401.

As described above, the embodiments of the present invention can provide, regarding a method of manufacturing a semiconductor device, a preferred method performed using a light absorption layer.

Examples of specific aspects of the present invention are described with reference to the first and second embodiments. However, the present invention is not limited to these embodiments.

1. A method of manufacturing a semiconductor device, the method comprising:
forming patterns on a substrate;
depositing a light absorption layer on the patterns;
processing the light absorption layer to form a first region which includes a first type of pattern included in the patterns and is coated with the light absorption layer having a first thickness, a second region which includes a second type of pattern included in the patterns and is coated with the light absorption layer having a second thickness thinner than the first thickness, and a third region which includes a third type of pattern included in the patterns and is coated with the light absorption layer having a third thickness thinner than the second thickness; and
annealing the substrate by radiating light on the substrate.

2. The method according to claim 1, further comprising:
forming a gate insulation film on the substrate; and
forming a gate electrode on the gate insulation film;
wherein,
the light absorption layer is deposited on the substrate and the gate electrode, and
the patterns are formed of a conductive layer forming the gate electrode.

3. The method according to claim 2, further comprising:
forming the first region in a region where the conductive layer is formed on a substrate region,
forming the second region in a region where the conductive layer is formed on an isolation layer, and an area of the isolation layer is smaller than a threshold, and
forming the third region in a region where the conductive layer is formed on an isolation layer, and an area of the isolation layer is larger than the threshold.

4. The method according to claim 3, wherein,
the first region includes, as the first type of pattern, the conductive layer formed on the substrate region,
the second region includes, as the second type of pattern, the conductive layer formed on the isolation layer having the area smaller than the threshold, and
the third region includes, as the third type of pattern, the conductive layer formed on the isolation layer having the area larger than the threshold.

5. The method according to claim 1, further comprising:
forming a gate insulation film on the substrate;
forming a gate electrode on the gate insulation film;
forming an interlayer insulation film on the substrate and the gate electrode;
processing the interlayer insulation film to form contact holes where the surfaces of the substrate and the gate electrode are exposed; and
forming a metal layer for silicidation on the surfaces of the substrate and the gate electrode;
wherein,
the light absorption layer is deposited on the metal layer, and,
the patterns are formed of silicide regions to be silicided by the metal layer.

6. The method according to claim 5, further comprising:
forming the first region in a region where a ratio of an area of the silicide regions within an area of a predetermined region is larger than a first threshold “X”,
forming the second region in a region where a ratio of an area of the silicide regions within an area of a predetermined region is smaller than the first threshold “X” and larger than a second threshold “Y”, and
forming the third region in a region where a ratio of an area of the silicide regions within an area of a predetermined region is smaller than the second threshold “Y” (where 0<Y<X<1).

7. The method according to claim 6, wherein,
the first region includes, as the first type of pattern, the silicide regions formed in the region where the ratio is larger than the first threshold “X”,
the second region includes, as the second type of pattern, the silicide regions formed in the region where the ratio is smaller than the first threshold “X” and larger than the second threshold “Y”, and
the third region includes, as the third type of pattern, the silicide regions formed in the region where the ratio is smaller than the second threshold “Y”.

8. The method according to claim 1, wherein the light absorption layer includes a silicon oxide layer or/and a silicon nitride layer.

9. The method according to claim 1, wherein the light absorption layer includes a layer containing carbon.

10. The method according to claim 1, wherein the light absorption layer is processed to form the light absorption layer whose thickness is changed in three or more levels within a range of a chip.

11. The method according to claim 1, wherein the substrate is heated to a temperature of 1,000° C. or higher by the annealing.

12. The method according to claim 1, wherein the light absorption layer is removed from the substrate after the annealing.

13. The method according to claim 1, wherein the difference in light absorptance between the first region and the third region is at least 10%.

14. The method according to claim 1, wherein the light is a laser beam, a halogen lamp beam, or a flash lamp beam.

15. The method according to claim 1, wherein the light is a laser beam or a flash lamp beam containing at least light having a wavelength of 0.4 to 20 μm.

16. A method of manufacturing a semiconductor device, the method comprising:
forming patterns on a substrate;
depositing a light absorption layer on the patterns;
processing the light absorption layer to form a first region which includes a first type of pattern included in the patterns and is coated with the light absorption layer having a first thickness, a second region which includes a second type of pattern included in the patterns and is coated with the light absorption layer having a second thickness thinner than the first thickness, and a third region which includes a third type of pattern included in the patterns and from which the light absorption layer is removed; and
annealing the substrate by radiating light on the substrate.

17. The method according to claim 16, further comprising:
forming a gate insulation film on the substrate; and
forming a gate electrode on the gate insulation film;
wherein,
the light absorption layer is deposited on the substrate and the gate electrode, and
the patterns are formed of a conductive layer forming the gate electrode.

18. The method according to claim 17, further comprising:
forming the first region in a region where the conductive layer is formed on a substrate region,
forming the second region in a region where the conductive layer is formed on an isolation layer, and an area of the isolation layer is smaller than a threshold, and
forming the third region in a region where the conductive layer is formed on an isolation layer, and an area of the isolation layer is larger than the threshold.

19. The method according to claim 16, further comprising:
forming a gate insulation film on the substrate;
forming a gate electrode on the gate insulation film;
forming an interlayer insulation film on the substrate and the gate electrode;
processing the interlayer insulation film to form contact holes where the surfaces of the substrate and the gate electrode are exposed; and
forming a metal layer for silicidation on the surfaces of the substrate and the gate electrode;
wherein,
the light absorption layer is deposited on the metal layer, and,
the patterns are formed of silicide regions to be silicided by the metal layer.

20. The method according to claim 19, further comprising:
forming the first region in a region where a ratio of an area of the silicide regions within an area of a predetermined region is larger than a first threshold “X”,
forming the second region in a region where a ratio of an area of the silicide regions within an area of a predetermined region is smaller than the first threshold “X” and larger than a second threshold “Y”, and
forming the third region in a region where a ratio of an area of the silicide regions within an area of a predetermined region is smaller than the second threshold “Y” (where 0<Y<X<1).
